(19) United States
(12) Patent Application Publication
(10) Pub. No.: US 2011/0048778 A1
(43) Pub. Date: Mar. 3, 2011

(54) Circuit board, semiconductor package and method of manufacturing the same

(75) Inventors: Jong Woo Han, Seongnam (KR); Soon Gvu Yim, Seongnam (KR); Young Do Kweon, Seoul (KR)

(73) Assignee: SAMSUNG ELECTRO-MECHANICS CO., LTD., Suwon (KR)

(21) Appl. No.: 12/654,306

(22) Filed: Dec. 16, 2009

(30) Foreign Application Priority Data
Sep. 1, 2009 (KR) 10-2009-0082209

(51) Int. Cl. H05K 1/16; H05K 1/11; H05K 3/10

(52) U.S. Cl. 174/260; 174/262; 29/846

(57) ABSTRACT

A circuit board includes a board part including a pattern portion on one surface thereof, the pattern portion being electrically connected to a semiconductor chip, and an under-fill layer disposed on the board part and exposing the pattern portion to the outside, the under-fill layer flowing to cover the pattern portion by heat generated in mounting the semiconductor chip.

### CROSS-REFERENCE TO RELATED APPLICATIONS

This application claims the priority of Korean Patent Application No. 10-2009-0082209 filed on Sep. 1, 2009, in the Korean Intellectual Property Office, the disclosure of which is incorporated herein by reference.

### BACKGROUND OF THE INVENTION

1. Field of the Invention

The present invention relates to a circuit board, a semiconductor package, and a method of manufacturing the same, and more particularly, to a circuit board including a separate under-fill layer, a semiconductor package including the circuit board, and a method of manufacturing the circuit board.

2. Description of the Related Art

One of main technique development trends in the semiconductor industry is a reduction in the size of semiconductor devices.

In order to realize slim and light semiconductor devices, the followings are required: techniques for reducing the sizes of individual mounting components, system-on-chip (SOC) techniques for implementing a plurality of individual devices as a single chip, and techniques for integrating a plurality of individual devices into a single package.

In general, a semiconductor device is mounted on a circuit board using flip-chip bonding. In this case, a solder ball is mounted on the bottom of the semiconductor device, and this solder ball contacts a connection pad on the surface of the circuit board. Thereafter, heat is applied to the vicinity of the solder ball so as to achieve an electrical connection between the semiconductor device and the connection pad. In addition, a liquid under-fill resin is filled between the semiconductor device and a solder resist layer of the circuit board and then cured (hardened).

However, an existing under-fill process requires high unit costs, and is susceptible to defects such as the undesired absence of an under-fill portion around a pattern portion placed inside. Therefore, techniques allowing for the omission of such a process are currently in demand.

### SUMMARY OF THE INVENTION

An aspect of the present invention provides a circuit board including an under-fill layer formed on a board part, a semiconductor package, and a method of manufacturing the circuit board.

According to an aspect of the present invention, there is provided a circuit board including: a board part including a pattern portion on one surface thereof, the pattern portion being electrically connected to a semiconductor chip; and an under-fill layer disposed on the board part to expose the pattern portion to the outside, the under-fill layer flowing to cover the pattern portion by heat generated in mounting the semiconductor chip.

The under-fill layer may be disposed on the board part and includes an opening wider than the pattern portion.

The under-fill layer may be disposed on the board part and exposes the pattern portion in part.

The circuit board may further include a solder resist layer disposed between the board part and the under-fill layer to protect a circuit pattern formed in the board part.

The solder resist layer may include an opening to expose the pattern portion to the outside, and the under-fill layer may include an opening having a size that is equal to or greater than the opening of the solder resist layer.

According to another aspect of the present invention, there is provided a semiconductor package including: a semiconductor chip including a conductive adhesive attached on a bottom surface thereof; and a circuit board including a board part including a pattern portion on one surface thereof, the pattern portion being electrically connected to the semiconductor chip, and an under-fill layer disposed on the board part and exposing the pattern portion to the outside, the under-fill layer flowing to cover the pattern portion by heat generated in mounting the semiconductor chip.

The semiconductor package may further include a solder resist layer disposed between the board part and the under-fill layer to protect a circuit pattern formed in the board part.

The solder resist layer may have an opening to expose the pattern portion to the outside, and the under-fill layer may have an opening having a size that is equal to or greater than the opening of the solder resist layer.

According to another aspect of the present invention, there is provided a method of manufacturing a circuit board, the method including: forming a pattern portion on a top surface of a board part; forming an under-fill layer on the board part to cover the pattern portion by heat generated in mounting a semiconductor chip; and exposing the pattern portion to the outside through the under-fill layer.

The forming of the pattern portion on the top surface of the board part may include forming a solder resist layer for protecting an upper portion of the pattern portion.

The exposing of the pattern portion may include forming the under-fill layer using a mask placed on the pattern portion so as to expose the pattern portion to the outside.

The exposing of the pattern portion may include forming an opening in the under-fill layer by using a laser, corresponding to a location of the pattern portion.

The exposing of the pattern portion may include forming an opening in the under-fill layer by emitting light thereto, the under-fill layer being formed of a photosensitive material.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a circuit board according to an exemplary embodiment of the present invention;

FIGS. 2A through 2C are cross-sectional views for explaining a method of manufacturing a semiconductor package according to an exemplary embodiment of the present invention;

FIGS. 3A through 3D are cross-sectional views for explaining a method of manufacturing a circuit board according to an exemplary embodiment of the present invention;

FIGS. 4A through 4C are cross-sectional views for explaining a method of manufacturing a circuit board according to another exemplary embodiment of the present invention; and

FIGS. 5A through 5C are cross-sectional views for explaining a method of manufacturing a circuit board according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, like reference numerals in the drawings denote like elements.

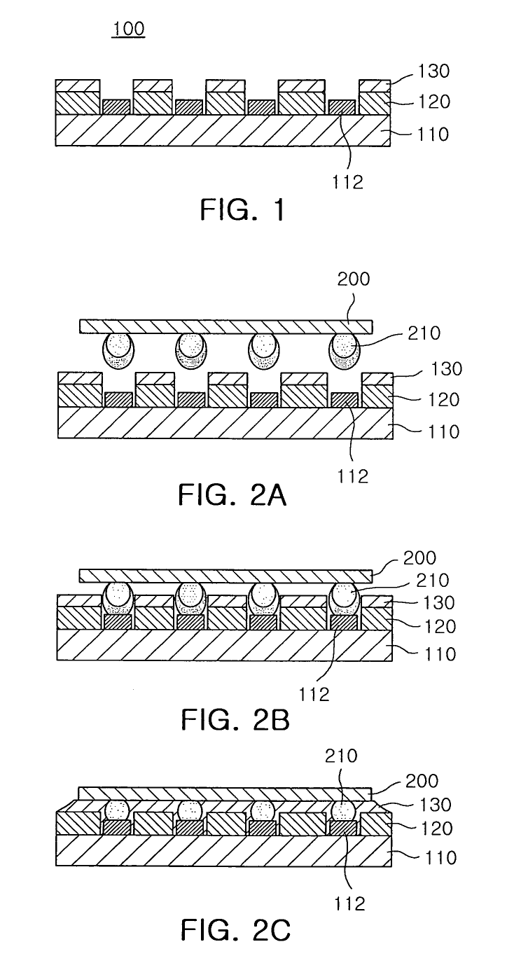

A circuit board, a semiconductor package and a method of manufacturing a circuit board will now be described in detail with reference to FIGS. 1 through 5C.

FIG. 1 is a cross-sectional view illustrating a circuit board according to an exemplary embodiment of the present invention.

Referring to FIG. 1, a circuit board 100 may include a board part 110, a solder resist layer 120 and an under-fill layer 130.

Pattern portions 112 are provided on the surface of the board part 110 for an electrical connection with a semiconductor chip (see 200 in FIGS. 2A through 2C). The board part 110 may utilize an organic board, a ceramic board employing low-temperature co-fired ceramics, or the like.

In addition, the solder resist layer 120 and the under-fill layer 130 may be placed sequentially on the board part 110 around the pattern portions 112. The board part 110 may be manufactured using a plurality of layers, and a circuit pattern may be provided in order to electrically connect the plurality of layers.

The solder resist layer 120 is provided on the surface of the board part 110 in the vicinity of the pattern portions 112 so as to expose the pattern portions 112.

The solder resist layer 120 serves for the alleviation of thermal stress as well as for electrical insulation, and may be formed of an insulating material containing a polymer. The solder resist layer 120 may be formed of an insulating material containing a photosensitive polymer in order to allow for the exposure of the pattern portions 112 to the outside. The insulating material may be selectively subjected to light-exposure and development to thereby expose the pattern portions 112 to the outside.

Although this embodiment includes the solder resist layer 120, the present invention is not limited to the description and the solder resist layer 120 may be omitted.

The under-fill layer 130 is disposed on the solder resist layer 120, and may have the same size as the solder resist layer 120. Thus, like the solder resist layer 120, the under-fill layer 130 may also be provided, exposing the pattern portions 112.

The under-fill layer 130 serves to enhance bonding strength with the semiconductor chip against external impact.

Therefore, the under-fill layer 130 is formed of a polymer having fluidity, so that the under-fill layer 130 flows to the exposed pattern portions 112 when heated in the process of mounting the semiconductor chip 200.

According to this embodiment, the under-fill layer 130 is automatically melted and flows toward the pattern portions 112 at the time of mounting the semiconductor chip on the circuit board. Consequently, a reflow process that is performed after injecting a separate under-fill material is omitted, thereby simplifying the manufacturing process and thus enhancing productivity.

Moreover, according to this embodiment, the under-fill layer 130, formed in the vicinity of the pattern portions 112, flows to an empty area in the circuit board 100 during thermal processing to thereby completely fill the empty area. Accordingly, a defect such as the undesired absence of the under-fill layer 130 in the board part 110 can be prevented.

FIGS. 2A through 2C are cross-sectional views illustrating a semiconductor package according to an exemplary embodiment of the present invention.

Referring to FIGS. 2A through 2C, a semiconductor package may include a semiconductor chip 200 and the circuit board.

The semiconductor chip 200 is connected onto a board part 110, and may include solder balls 210 formed of a conductive adhesive and mounted on the bottom of the semiconductor chip 200. The solder balls 210 on the bottom of the semiconductor chip 200 are spaced apart from each other, corresponding to the locations of the pattern portions 112 of the board part 110.

The circuit board may include the board part 110, a solder resist layer 120 and an under-fill layer 130, and detailed description thereof may be omitted since it has the same construction as in the above-described construction.

Referring to FIG. 2A, the semiconductor chip 200 is disposed on the board part 110 with its solder balls 210 corresponding to the pattern portions 112 of the circuit board 100.

Referring to FIG. 2B, the semiconductor chip 200 and the board part 110 are made to contact each other so that the solder balls 210 of the semiconductor chip 200 contact the pattern portions 112 of the board part 110, respectively.

Thereafter, heating is performed to thereby melt the solder balls 210 of the semiconductor chip 200 and cause them to contact the pattern portions 112 for an electrical connection therebetween. At this time, by this heating, the under-fill layer 130 is also melted and flows towards the pattern portions 112 as shown in FIG. 2C.

That is, the under-fill layer on the board part 110 is automatically melted in the process of mounting the semiconductor chip 200, and flows toward the pattern portions 112. This allows for the omission of a reflow process that is performed after the injection of a separate under-fill material. Accordingly, the semiconductor package of this embodiment can be manufactured using simpler processes with higher productivity.

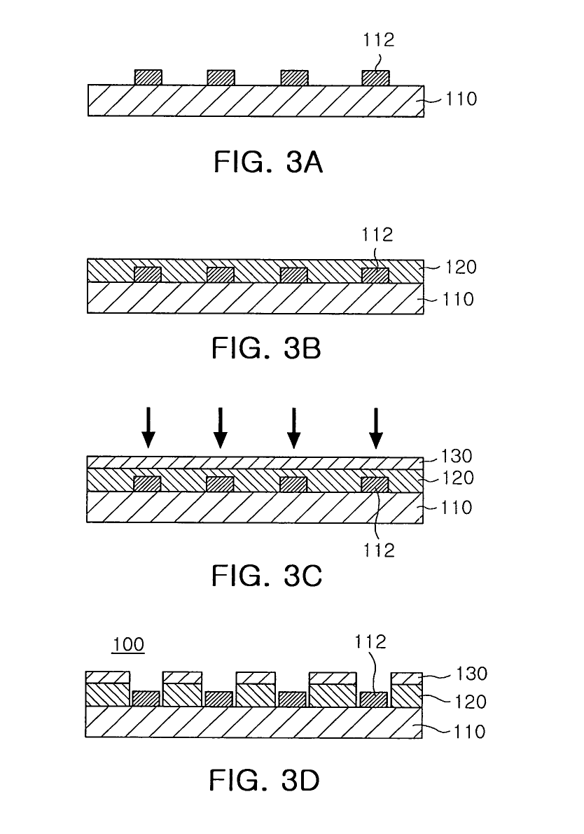

FIGS. 3A through 3D are cross-sectional views for explaining a method of manufacturing a circuit board according to an exemplary embodiment of the present invention.

As shown in FIG. 3A, the method of manufacturing the circuit board 100 may include forming pattern portions 112 on the top surface of a board part 110.

As shown in FIG. 3B, a solder resist layer 120 is formed on the board part 110 to cover the pattern portions 112. Here, the solder resist layer 120 may be formed of a glass material.

After the solder resist layer 120 is formed on the pattern portions 112, as shown in FIG. 3C, an under-fill layer 130 of a polymer material may be disposed on the solder resist layer 120.

Subsequently, laser processing (see arrows in FIG. 3C) is performed according to the location of the pattern portions 112 and melts the solder resist layer 120 and the under-fill layer 130. Consequently, as shown in FIG. 3D, the solder resist layer 120 and the under-fill layer 130 are formed around the pattern portions 112, exposing the pattern portions 112 entirely.

However, the present invention is not limited to exposing the pattern portions 112 entirely across the circuit part 110, and the pattern portions 112 may be partially exposed.

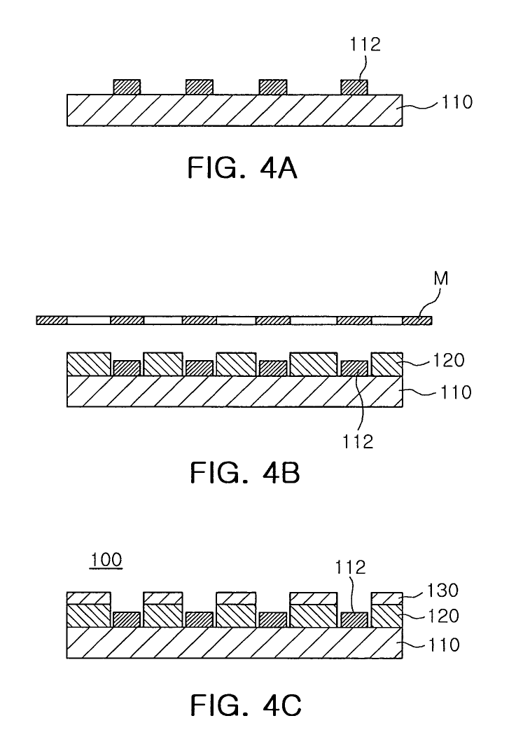

FIGS. 4A through 4C are cross-sectional views for explaining a method of manufacturing a circuit board according to another exemplary embodiment of the present invention.

Referring to FIG. 4A, the method of manufacturing a circuit board 100 may include forming pattern portions 112 on the top surface of a board part 110.

After the pattern portions 112 are formed on the top surface of the board part 110, a solder resist layer 120 is formed to cover the upper portions of the pattern portions 112 on the board part 110.

Here, the solder resist layer 120 may be formed of an insulating layer containing a photosensitive polymer in order to expose the pattern portions 112. The solder resist layer 120 may be subjected to light-exposure and development processes so as to expose the pattern portions 112 and the vicinity thereof to the outside.

Subsequently, as shown in FIG. 4B, a mask M having openings is placed on the solder resist layer 120 for the process of forming an under-fill layer 130.

After the solder resist layer 120 is formed on the board part 110, as shown in FIG. 4C, an under-fill layer 130 having the same size as the solder resist layer 120 may be provided on the solder resist layer 120 by using a screen-printing process through the openings of the mask M.

Accordingly, the solder resist layer 120 and the under-fill layer 130 may have openings of the same size in order to expose the pattern portions 112 to the outside. However, the present invention is not limited to the above description, the openings of the under-fill layer 130 may be greater than those of the solder resist layer 120.

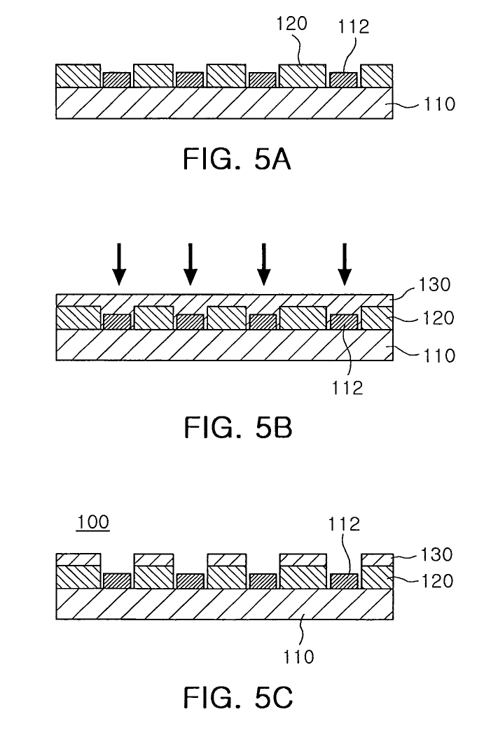

FIGS. 5A through 5C are cross-sectional views for explaining a method of manufacturing a circuit board according to another exemplary embodiment of the present invention.

Referring to FIG. 5A, the method of manufacturing a circuit board 100 may include forming pattern portions 112 on the top surface of a board part 110.

After the pattern portions 112 are formed on the board part 110, a solder resist layer 120 is formed to cover the upper portions of the pattern portions 112.

The solder resist layer 120 may be formed of a photosensitive polymer in order to expose the pattern portions 112. The solder resist layer 120 may be subjected to light-exposure and development processes to thereby expose the pattern portions 112 and the vicinity of the pattern portions 112.

Also, an under-fill layer 130 may be formed in a way that covers the solder resist layer 120 and the pattern portions 112. A laser is emitted toward the pattern portions 112 (see arrows in FIG. 5B) so that the pattern portions 112 and the vicinity thereof are completely exposed. Through the above process, the under-fill layer 130 may be provided only on the solder resist layer 120 as shown in FIG. 5C.

In this embodiment, the pattern portions 112 are opened by melting the under-fill layer 130 using a laser process. However, the invention is not limited to the description, and an etching process may be used.

Accordingly, the method of manufacturing a circuit board according to this embodiment forms the under-fill layer 130 on the board part 110, thereby simplifying a manufacturing process and thus allowing for the omission of a reflow process performed after an under-fill material is injected.

Moreover, since the under-fill layer 130 is formed on the board part 110 so as to expose the pattern portions 112 to the outside, the under-fill layer 130 re-flows into each empty area, and thus completely fills such empty areas. Accordingly, the circuit board, the semiconductor package and the method of manufacturing the circuit board, according to this embodiment, can prevent a defect such as the undesired absence of the under-fill layer 130.

As set forth above, in the circuit board, the semiconductor package and the method of manufacturing the circuit board according to exemplary embodiments of the invention, a reflow process performed after the injection of a separate under-fill material is omitted since an under-fill layer is formed on a board part, thereby simplifying the manufacturing process thereof.

In addition, in the circuit board, the semiconductor package and the method of manufacturing the circuit board according to exemplary embodiments, the under-fill layer is formed near each empty area around pattern portions to thereby flow to each empty area during thermal processing. Accordingly, the defect of the undesired random absence of the under-fill layer in the board part can be prevented.

While the present invention has been shown and described in connection with the exemplary embodiments, it will be apparent to those skilled in the art that modifications and variations can be made without departing from the spirit and scope of the invention as defined by the appended claims.

What is claimed is:

1. A circuit board comprising:
a board part including a pattern portion on one surface thereof, the pattern portion being electrically connected to a semiconductor chip; and
an under-fill layer disposed on the board part and exposing the pattern portion to the outside, the under-fill layer flowing to cover the pattern portion by heat generated in mounting, the semiconductor chip.

2. The circuit board of claim 1, wherein the under-fill layer is disposed on the board part and includes an opening wider than the pattern portion.

3. The circuit board of claim 1, wherein the under-fill layer is disposed on the board part and exposes the pattern portion in part.

4. The circuit board of claim 1, further comprising a solder resist layer disposed between the board part and the under-fill layer to protect a circuit pattern formed in the board part.

5. The circuit board of claim 4, wherein the solder resist layer includes an opening to expose the pattern portion to the outside, and the under-fill layer includes an opening having a size that is equal to or greater than the opening of the solder resist layer.

6. A semiconductor package comprising:
a semiconductor chip including a conductive adhesive attached on a bottom surface thereof; and
a circuit board comprising:
a board part including a pattern portion on one surface thereof, the pattern portion being electrically connected to the semiconductor chip; and
an under-fill layer disposed on the board part and exposing the pattern portion to the outside, the under-fill layer flowing to cover the pattern portion by heat generated in mounting the semiconductor chip.

7. The semiconductor package of claim 6, further comprising a solder resist layer disposed between the board part and the under-fill layer to protect a circuit pattern formed in the board part.

8. The semiconductor package of claim 7, wherein the solder resist layer includes an opening to expose the pattern portion to the outside, and the under-fill layer includes an opening having a size that is equal to or greater than the opening of the solder resist layer.

9. A method of manufacturing a circuit board, the method comprising:
forming a pattern portion on a top surface of a board part;
forming an under-fill layer on the board part, the under-fill layer covering the pattern portion by heat generated in mounting a semiconductor chip; and
exposing the pattern portion to the outside through the under-fill layer.

10. The method of claim 9, wherein the forming of the pattern portion on the top surface of the board part comprises forming a solder resist layer for protecting an upper portion of the pattern portion.

11. The method of claim 9, wherein the exposing of the pattern portion comprises forming the under-fill layer using a mask placed on the pattern portion so as to expose the pattern portion to the outside.

12. The method of claim 9, wherein the exposing of the pattern portion comprises forming an opening in the under-fill layer by using a laser, corresponding to a location of the pattern portion.

13. The method of claim 9, wherein the exposing of the pattern portion comprises forming an opening in the under-fill layer by emitting light thereto, the under-fill layer being formed of a photosensitive material.
